(19) United States
(12) Patent Application Publication
(10) Pub. No.: US 2004/0096021 A1
(43) Pub. Date: May 20, 2004

(54) Communications methods for narrow band demodulation

(75) Inventor: Ronald J. Koval, Aurora, IL (US)

Correspondence Address: ALLEN, DYER, DOPPELT, MILBRATH & GILCHRIST P.A., 1401 CITRUS CENTER 255 SOUTH ORANGE AVENUE, P.O. BOX 3791, ORLANDO, FL, 32802-3791, US

(73) Assignee: UNB Technologies, Inc., Orlando, FL

(21) Appl. No.: 10/294,152

(22) Filed: Nov. 14, 2002

(51) Int. Cl. H03K 9/00; H04L 27/06

(52) U.S. Cl. 375/350

(57) ABSTRACT

A narrow band signal demodulation method may include receiving a modulated narrow band signal based upon a carrier frequency signal and a level periodically inserted over a predetermined portion of a carrier cycle and representing digital data. The method may further include converting the modulated narrow band signal into frequency domain components, and translating the frequency domain components into the digital data based upon levels at the carrier frequency component. By way of example, the predetermined portion of the carrier cycle may be one full carrier cycle. Thus, received digital data may have been mapped into a first corresponding level during a first half-cycle of the full carrier cycle, and into a second corresponding level during a second half-cycle of the full carrier cycle.

### FIELD OF THE INVENTION

The present invention relates to the field of communications systems, and, more particularly, to modulators and demodulators therefor and related methods.

### BACKGROUND OF THE INVENTION

Wireless communication systems typically operate within a very well defined frequency spectrum or band. By way of example, radio stations within a certain geographic area transmit frequency modulated (FM) or amplitude modulated (AM) signals at different carrier frequencies so that their respective transmissions do not overlap and cause interference. Another example is cellular telephone networks, in which a wireless microwave link is often used for communicating between a remotely located cell tower and a mobile switching center. Here again, these microwave links have to be well defined so that they do not overlap with one another.

In the U.S., for example, the Federal Communications Commission (FCC) allocates specific frequency bands to different communication system operators. Each frequency band has a central frequency range, and peak signal energy which can be used within this central frequency range is typically limited.

Moreover, it is often necessary to define transition bands between adjacent frequency bands to prevent signal energy from leaking or bleeding from one frequency band into the other. Generally speaking, transmitted signal energy will taper off within the transmission bands near the limits of the frequency band. In some applications, these limits will be well defined, and such limits are typically referred to as stop bands. In other applications no absolute stop bands are defined, and the transition band may be conceptually thought of as a guard band or unused range between frequency bands in which signals from adjacent frequency bands taper off.

It should be noted that the above-described frequency band allocation is not limited strictly to wireless communications systems. For example, fiber optic networks can be used for transmitting signals over a broad frequency range. Thus, in such instances it is also necessary to clearly define distinct frequency bands for fiber as well as metallic wired communications as well.

Accordingly, to transmit a signal across a particular frequency band in either a wired or wireless medium, the signal has to be modulated to correspond to the particular central (or carrier) frequency of the frequency band. Various prior art approaches have been developed for modulating signals. The principal goal of such modulation techniques is to reliably transfer the most data, as fast as possible, over the given medium and within the regulations noted above.

Given the above, most modulation techniques produce signals that have a majority of their signal energy levels concentrated in the center of the frequency band. Such modulation techniques as frequency shift keying (FSK), phase shift keying (PSK), quadrature amplitude modulation (QAM), and others even add filtering to compensate for the harmonics and transients produced by attempting to maximize the data carrying capacity of the frequency band. As such, these techniques may conceptually be thought of as wide band techniques.

A less common modulation technique is narrow band modulation. One example of a narrow band modulation technique is described in U.S. Pat. No. 6,445,737. This technique implements phase reversal keying and pulse position modulation. More particularly, this technique implements missing carrier cycles or carrier cycle phase reversal to produce a principle peak signal along with minor peak signals. The principle peak signal occupies a very narrow frequency bandwidth, while the minor peak signals are disregarded. Filtering is added to reduce minor peak signal levels. Over a fixed number of cycles of a carrier frequency, such modulation codes data to two operational states, namely the presence of a normal carrier cycle or a cycle containing a missing pulse/phase reversed cycle.

An illustrative example of such a narrow band modulated signal 50 with missing pulses 51 is illustratively shown in the time domain waveform diagram of FIG. 7. The missing pulses 51 occur (or not) every sixth carrier cycle 52. Thus, in the illustrated example, the first five successive cycles will be carrier frequency cycles, and the sixth cycle will either include a pulse (which is the same as a carrier pulse in the previous five cycles) or no pulse. While this ratio is chosen in the present example for clarity of illustration, larger numbers of carrier cycles between missing pulses will likely be used in most applications.

Another example is set forth in U.S. Pat. No. 5,930,303, which describes a modulation technique known as very minimum shift keying (VMSK). VMSK implements very minute phase shifts in its modulation. Maintaining the phase shifts to minimal transitions is critical in maintaining a resultant narrow frequency band.

Other modulation techniques, whether amplitude, phase, combinations of amplitude and phase, or pulse positioning produce significant frequency bandwidth that is a function of the carrier frequency, bit modulation and data rate. Demodulation of these narrow band modulation signals is typically performed using time domain signal transitions with wave shaping and filtering to deliver the signal to a level threshold detector (e.g., a comparator or logic gate). In such implementations, a continuous data stream of either ones or zeros (depending on the data mapping design choice) results in the carrier signal.

The minute phase shifts of VMSK modulation produce a signal that has some degree of spread spectrum or wide band characteristics. Improving on the narrow band approach, the missing pulse and phase reversal technique described in U.S. Pat. No. 6,445,737 produces a desirably narrower modulation carrier signal with lower level minor peaks. Even so, both phase reversal and missing pulse modulation still produce undesirable minor peaks which may require several orders of added filtering to reduce to acceptable levels. Moreover, both of the phase reversal and missing pulse techniques modulate a single data bit for a given number of carrier cycles. Thus, to increase the data rate requires reducing the number of carrier cycles, which undesirably increases the modulation harmonics or minor peaks.

### SUMMARY OF THE INVENTION

In view of the foregoing background, it is therefore an object of the present invention to provide narrow band demodulation methods which allow for frequency domain demodulation of narrow band modulated signals.

This and other objects, features, and advantages in accordance with the present invention are provided by a narrow band signal demodulation method which may include receiving a modulated narrow band signal based upon a carrier frequency signal and a level periodically inserted over a predetermined portion of a carrier cycle and representing digital data. The method may further include converting the modulated narrow band signal into frequency domain components, and translating the frequency domain components into the digital data based upon levels at the carrier frequency component.

By way of example, the predetermined portion of the carrier cycle may be one full carrier cycle. Thus, received digital data may have been mapped into a first corresponding level during a first half-cycle of the full carrier cycle, and into a second corresponding level during a second half-cycle of the full carrier cycle. Alternately, the predetermined portion of the carrier cycle may be one-half of the carrier cycle, and the received digital data may thus have been mapped into a single corresponding level over the half-cycle of the carrier cycle. In either case, the demodulation in accordance with the invention advantageously allows for the detection of data signal loss as a function of discrete frequency level changes during the predetermined portion of the carrier cycle. The carrier frequency may be in a range of about 10 MHz to 2 GHz, for example.

Moreover, by performing frequency domain conversion prior to data transformation, the method of the invention thus allows for accurate data reconstruction without the need for the minor peaks required for time domain processing. By way of example, the frequency domain conversion may include performing Fourier transforms or wavelet transforms.

Furthermore, the data translation may include performing adaptive filtering to advantageously train and detect data from the carrier frequency components while filtering other interferences. The method may also include generating a data clock based upon the digital data, and outputting the digital data based upon the data clock.

Another advantageous method aspect of the invention is for increasing capacity of a communications terminal comprising a receiver for receiving modulated signals from a remote terminal and at least one wide band demodulator connected to the receiver. The method may include connecting at least one narrow band demodulator to the receiver for demodulating digital data from the remote terminal. More particularly, the at least one narrow band demodulator may include an input for receiving a modulated narrow band signal based upon a carrier frequency signal and a level periodically inserted over a predetermined portion of a carrier cycle and representing digital data. The at least one narrow band demodulator may also include a frequency domain converter for converting the modulated narrow band signal into frequency domain components, and a data translator for translating the frequency domain components into the digital data based upon levels at the carrier frequency component. The at least one wide band demodulator may also have a relatively wider frequency spectrum than a narrow frequency spectrum of the at least one narrow band modulator.

In one particularly advantageous embodiment, the receiver may receive a plurality of modulated narrow band signals, and connecting may include connecting a plurality of narrow band demodulators to the receiver and operating at the different carrier frequencies. Moreover, the relatively wider frequency spectrum may have at least one transition frequency band associated therewith, and the frequency spectrum of the at least one narrow band demodulator may be in the at least one transition frequency band. By way of example, the at least one wide band demodulator may be at least one of a frequency shift keying (FSK), phase shift keying (PSK), quadrature amplitude modulation (QAM) demodulator, quadrature phase shift keying (QPSK), and Gaussian minimum shift keying (GMSK), or similar wideband type demodulator.

The method may advantageously be used for communications terminals in numerous communications systems, such as cellular telephone systems, cable television systems, and fiber-optic systems, for example, where narrow band signal demodulation is desirable. This is particularly true where such systems implement transmission bands, as narrow band modulated signals located in such transitions bands may be readily detected and demodulated based upon their carrier frequency components, which thus allows for further bandwidth utilization over that provided solely by using a wide band modulator. As such, the receiver may be at least one of a radio receiver, a wireline receiver, and an optical receiver, for example.

### BRIEF DESCRIPTION OF THE DRAWINGS

FIG. 1 is schematic block diagram of a cellular communications system including narrow band modems in accordance with the present invention.

FIG. 2 is a schematic block diagram of a cable television communications system including narrow band modulators and demodulators in accordance with the present invention

FIG. 3 is a schematic block diagram of an alternate embodiment of the cable terminal of the cable television communications system of FIG. 2 which includes a wideband modem and has also be retrofitted to include narrow band modems in accordance with the present invention.

FIG. 4A is a schematic spectral frequency diagram illustrating the modulated wide band and narrow band signals from the cable television modulators of FIG. 3.

FIG. 4B is a schematic spectral frequency diagram illustrating the modulated wide band and narrow band signals from the microwave modems of FIG. 1.

FIG. 5 is schematic block diagram of the narrow band modulator of FIG. 2.

FIG. 6 is a schematic block diagram of the narrow band demodulator of FIG. 2.

FIG. 7 is a time domain waveform diagram illustrating a signal modulated using a narrow band modulator of the prior art.

FIG. 8 is a time domain waveform diagram illustrating a first signal modulated using the narrow band modulator of FIG. 5 with two data levels mapped over a half carrier cycle.

FIG. 9 is a time domain waveform diagram illustrating a second signal modulated using the narrow band modulator of FIG. 5 with four data levels mapped over a half carrier cycle.

FIG. 10 is a time domain waveform diagram illustrating a third signal modulated using the narrow band modulator of FIG. 5 with two data levels mapped over a full carrier cycle.

FIG. 11 is a time domain waveform diagram illustrating a fourth signal modulated using the narrow band modulator of FIG. 5 with four pairs of data levels mapped over a full carrier cycle.

FIG. 12 is a time domain waveform diagram illustrating a fifth signal modulated using the narrow band modulator of FIG. 5 with eight pairs of data levels mapped over a full carrier cycle.

FIG. 13 is a graph including spectral frequency plots of a narrow band signal modulated in accordance with the prior art, and also of a narrow band signal modulated using the narrow band modulator of FIG. 5 with two data levels mapped over a half carrier cycle.

FIG. 14 is a graph including spectral frequency plots of the prior art narrow band modulated signal of FIG. 13, and also of a narrow band signal modulated using the narrow band modulator of FIG. 5 with four data levels mapped over a half carrier cycle.

FIG. 15 is a graph including spectral frequency plots of the prior art narrow band modulated signal of FIG. 13, and also of a narrow band signal modulated using the narrow band modulator of FIG. 5 with two pairs of data levels mapped over a full carrier cycle.

FIG. 16 is a graph including spectral frequency plots of the prior art narrow band modulated signal of FIG. 13, and also of a narrow band signal modulated using the narrow band modulator of FIG. 5 with four pairs of data levels mapped over a full carrier cycle.

FIG. 17 is a graph including spectral frequency plots of the prior art narrow band modulated signal of FIG. 13, and also of a narrow band signal modulated using the narrow band modulator of FIG. 5 with eight pairs of data levels mapped over a full carrier cycle.

FIG. 18 is a flow diagram illustrating a narrow band modulation method in accordance with the present invention.

FIG. 19 is a flow diagram illustrating a narrow band demodulation method in accordance with the present invention.

### DETAILED DESCRIPTION OF THE PREFERRED EMBODIMENTS

The present invention will now be described more fully hereinafter with reference to the accompanying drawings, in which preferred embodiments of the invention are shown. This invention may, however, be embodied in many different forms and should not be construed as limited to the embodiments set forth herein. Rather, these embodiments are provided so that this disclosure will be thorough and complete, and will fully convey the scope of the invention to those skilled in the art. Like numbers refer to like elements throughout, and prime and multiple prime notation are used to indicate similar elements in alternate embodiments.

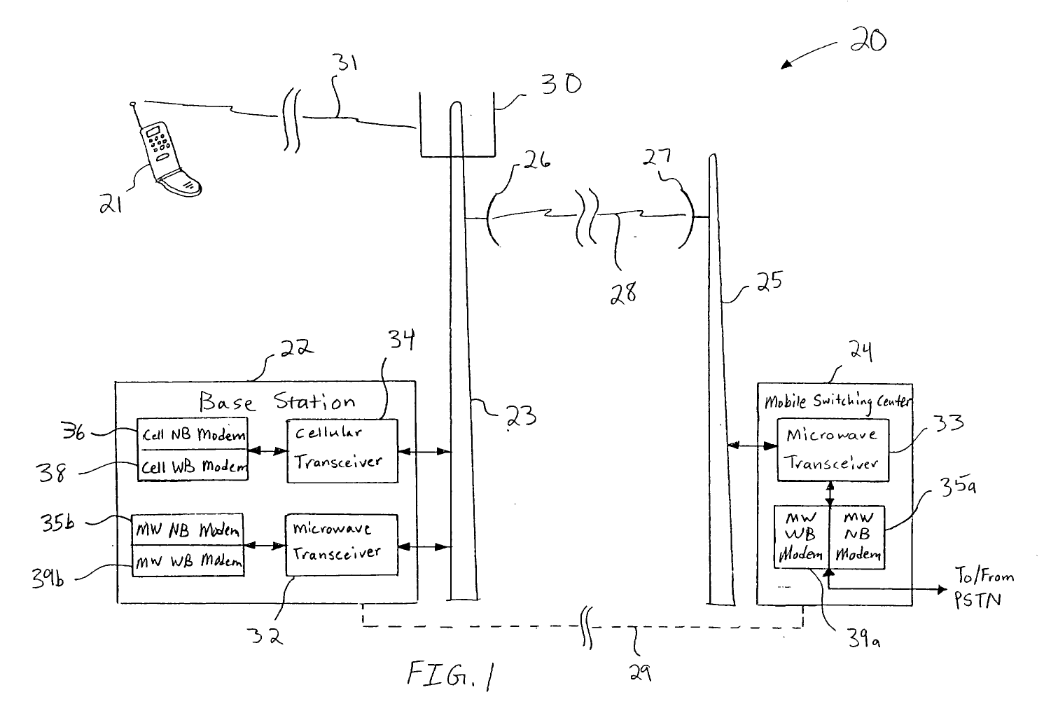

Referring initially to FIG. 1, a cellular communications system 20 in accordance with the invention is first described. In particular, the cellular communication system 20 illustratively includes three communications terminals, namely a cell phone 21, a base station 22, and a mobile switching center 24. The base station 22 has associated therewith a cell tower 23, and the mobile switching center 24 similarly has a tower 25 associated therewith. As will be appreciated by those of skill in the art, the base station 22 and cell tower 23 are typically located remotely from the mobile switching center 24, and the two communicate with one another via respective microwave antennas 26, 27 and transceivers 32, 33 over a microwave link 28. Of course, the base station 22 may in some embodiments be linked to the mobile switching center 24 via a wired link 29 (illustratively shown with dashed lines), such as a T1 or E1 line, instead of the microwave link 28, for example.

The mobile switching center 24 typically provides the user of the cell phone 21 access to a public switched telephone network (PSTN), as will also be appreciated by those of skill in the art. This is made possible because when the cell phone 21 comes within the signal range or “cell” of the base station 22, the cell phone 21 can send and receive signals through the mobile switching center 24 via the microwave link 28 and a cellular frequency communications link 31. More particular, the cell tower 23 illustratively includes one or more cellular antennas 30 which cooperate with a cellular transceiver 34 in the base station 22 for establishing the cellular frequency communications link 31 with the cell phone 21, which also includes a cellular transceiver (not shown).

As discussed briefly above, the particular frequency bands that may be used for the communications links 28 and 31 are strictly allocated and defined to ensure other signal transmissions within the relevant geographic area do not overlap and interfere with one another. Thus, the microwave link 28 will correspond to a particular microwave frequency band, and the base station 22 will also use a particular cellular frequency band to establish communications links with users.

As a result, most such cellular communications terminals include wide band modems for modulating/demodulating the signals sent over the frequency bands in an attempt to maximize usage of the central portion of the frequency band where greater signal amplitude is allowed. By way of example, the mobile switching center 24 and base station 22 respectively include microwave wide band modems 39a, 39b which typically implement quadrature amplitude modulation (QAM), for example. As used herein, QAM is meant to include 256 QAM and other variants thereof, as will be appreciated by those skilled in the art.

Further, the base station 22 also includes a cellular wide band modem 38 for modulating/demodulating cellular signals to be transmitted via the cellular link 31 to/from the cell phone 21, which will also include a similar modem (not shown). By way of example, typical cellular wide band modems may implement wide band techniques such as frequency shift keying (FSK), phase shift keying (PSK) techniques such as quadrature and n/4 quadrature phase shift keying (QPSK), and Gaussian minimum shift keying (GMSK). Of course, other suitable wide band techniques may also be used in accordance with the present invention.

In accordance with the present invention, the cell phone 21, base station 22, and mobile switching center 24 may also advantageously include one or more respective narrow band modems for modulating/demodulating digital data transmitted between the various terminals. In the illustrated example, the mobile switching center 24 includes a microwave narrow band modem 35a which cooperates with the microwave transceiver 33. The base station 22 includes cellular and microwave narrow band modems 36, 35b which respectively cooperate with the cellular and microwave transceivers 34, 32. The cell phone 21 also includes a narrow band modem (not shown) for cooperating with a cellular transceiver thereof. The operation and numerous advantages of using such narrow band modems in accordance with the present invention will be described further below.

It should be noted that, as used herein, the term “wide band” does not connote any particular minimum frequency range or bandwidth. Rather, this term is used merely to indicate a relatively wider frequency spectrum than a narrow frequency spectrum produced by the narrow band modems/modulators of the present invention, as will be understood by those skilled in the art.

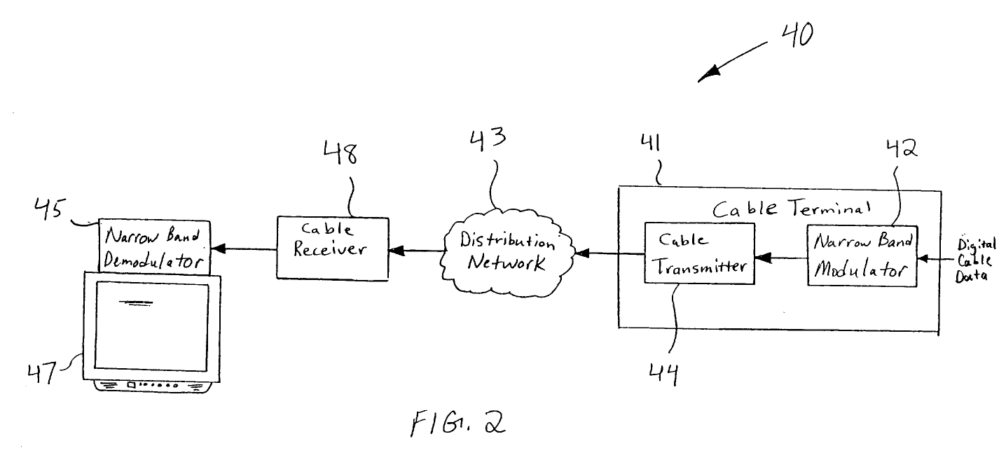

Turning now additionally to FIG. 2, an embodiment of a cable television communications system 40 in accordance with the present invention includes a cable terminal 41, which may advantageously use one or more narrow band modulators 42. The narrow band modulator 42 receives digital cable data and cooperates with a cable transmitter 44 to send modulated cable signals to subscribers via a distribution network 43 (which may include amplifiers, repeaters, etc.). These signals are then demodulated by a narrow band demodulator 45 to permit viewing on a television 47, for example, as will be understood by those skilled in the art. Of course, it will be appreciated by those skilled in the art that bi-directional communications could be used in the system 40 to provide Internet access, pay per view services, etc. in some embodiments, if desired.

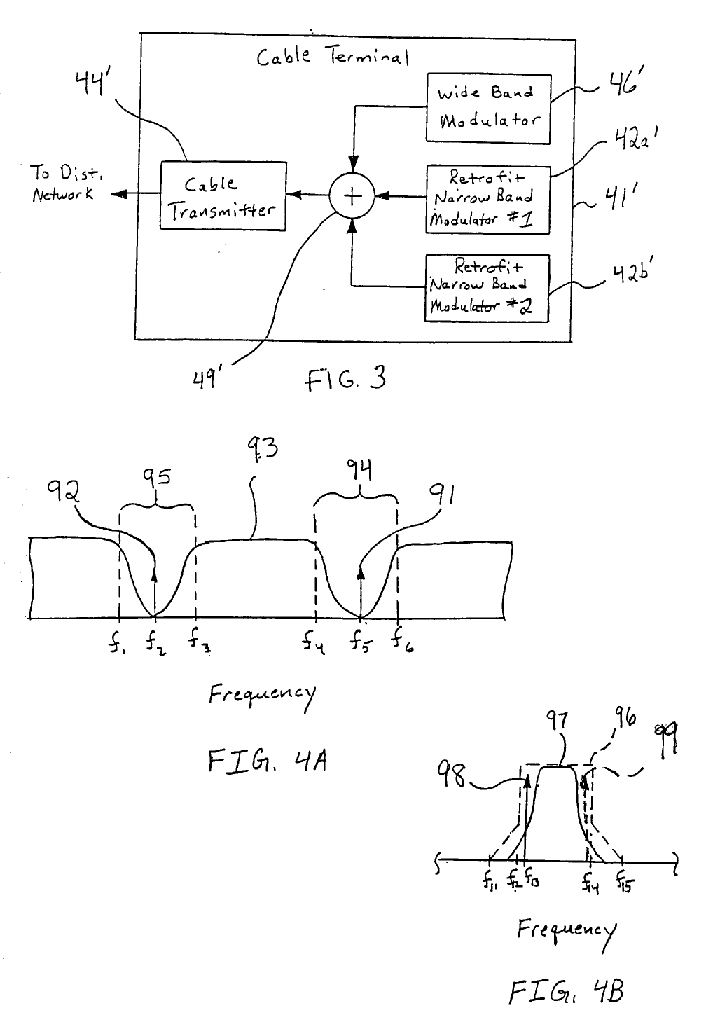

An alternate embodiment of the cable terminal 41′ which includes a pre-existing wide band modulator 46′ is illustrated in FIG. 3. In this embodiment, the cable terminal 41′ has also been retrofitted to include first and second narrow band modulators 42a′, 42b′. In the illustrated example, a signal combiner 49′ is also included for combining the various modulated signals before transmission by the cable transmitter 44′. Those of skill in the art will appreciate that such combiners and/or other equipment may be appropriate in various applications depending upon the type of transmitter being used, etc.

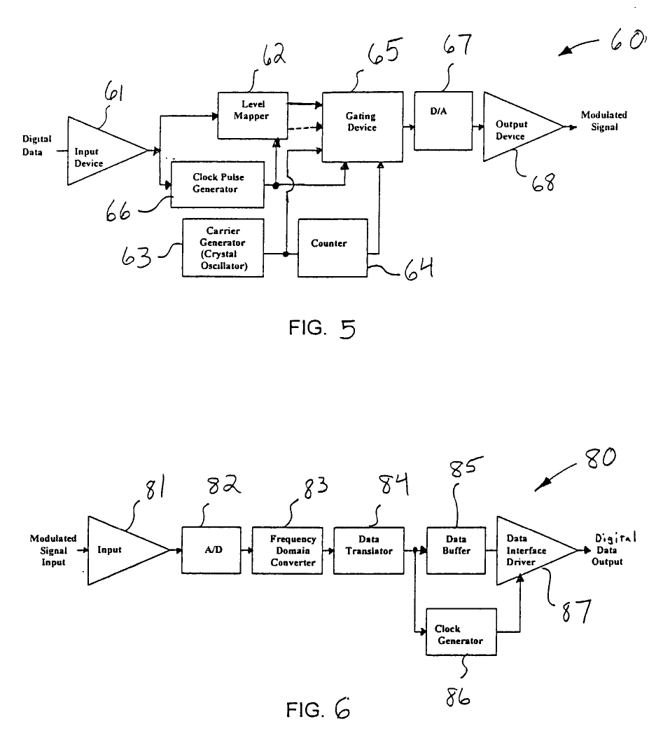

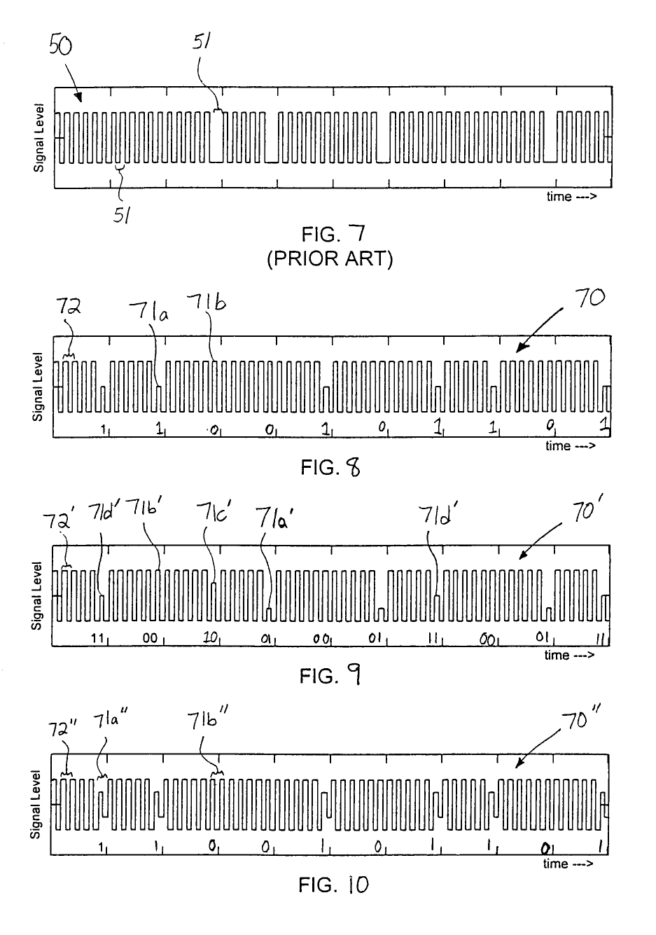

The advantages of retrofitting the cable terminal 41′ with the narrow band modulators 42a′, 42b′ will be understood with reference to the frequency spectral diagram of FIG. 4. As noted above, in many communications frequency bands (including both wired and wireless frequency bands), there will be upper and lower transition frequency bands associated therewith. The purpose of these transition bands is to ensure that the levels of signals transmitted in the frequency band do need bleed over into other transmissions sharing the same communications medium.

In the illustrated example, a modulated wide band signal 93 output from the wide band modulator 46′ (e.g., QAM) is centered within a frequency band which extends between frequencies f₁ and f₆. Moreover, transition bands 94, 95 cover a predetermined frequency range extending between the frequencies f₄, f₆, and f₁, f₃, respectively. As is illustratively shown, in the case of cable frequency bands (or channels), the transistion bands 94, 95 take the form of guard bands between adjacent frequency bands. Because of the very narrow band characteristics provided by the narrow band modulation of the present invention, which will be described further below, the frequency spectrum of the retrofit narrow band modulators 42a′, 42b′ may advantageously be located in one or both of the transition frequency bands 94, 95.

A spectral frequency diagram of the modulated wide band and narrow band signals 97, 98 generated by the microwave wide band modem 39a (or 39b) and the narrow band modem 35a (or 35b) of FIG. 1 are illustratively shown in FIG. 4B. In the case of a microwave frequency band, a more rigid definition of the particular limits of the frequency band is usually given, for example, by the FCC. In the present example, the absolute frequency band limits for the microwave link 28 are illustratively shown with the dashed outline 96. More particularly, stop bands at the frequencies f₁₁ and f₁₅ define the absolute lower and upper limits of the microwave frequency band, respectfully. Further, stop bands at the frequencies f₁₂ and f₁₄ define the limits between which the maximum signal energy may be used.

As illustratively shown, the modulated narrow band signal 98 from the microwave narrow band modem 35a (or 35b) may advantageously be positioned at the frequency f₁₃ to utilize the bandwidth which the wide band modulated signal 97 cannot, as will be appreciated by those skilled in the art. Of course, as was explained with reference to FIG. 4A above, other narrow band modulators may also optionally be added to provide one or more additional modulated narrow band signals 99 (illustratively shown with a dashed arrow) to provide still further bandwidth utilization. Additional signals could even be added in the ranges between the frequencies f₁₁ and f₁₃, and f₁₄ and f₁₅, as will also be appreciated by those skilled in the art.

In the present example, the carrier frequency component 91 of the modulated signal from the narrow band modulator 42a′ is located at the frequency f₅ in the upper transition band 94, and the carrier frequency component 92 from the narrow band modulator 42b′ is located in the lower transition band 95 at the frequency f₂. As such, by connecting one or both of the first and second modems 42a′, 42b′ to the cable transmitter 44′ in a pre-existing cable terminal 41′, the present invention thus provides a relatively inexpensive way to significantly increase bandwidth usage of a frequency band without interfering with the existing signal 93 or violating prescribed frequency band regulations, as will be further described below.

Before describing the modulator and demodulator components of the narrow band modem of the present invention in detail, it should be noted that the present invention may be implemented in numerous communications systems or networks beyond microwave, cellular and cable networks and with numerous communication mediums (e.g., wireless RF or microwave links, T1 or E1 lines, fiber optic lines, etc.). From the foregoing, it will be appreciated that the present invention is particularly well suited for applications in which a transition band is included between frequency bands, but it may also be used in other applications as well.

By way of example, narrow band modulation/demodulation in accordance with the present invention may advantageously be used in wireless applications such as wireless home networks, wireless video networks, cordless phones, pagers, remote medical monitors, broadcast satellite video applications, television station broadcasts (e.g., UHF/VHF), amateur radio, navigation, aeronautical applications, laser modulation, etc. Examples of wired applications may include local area networks (LANs), PBX distribution/switching, wave guides, fiber optic networks, etc. Those skilled in the art will understand how to apply the teachings of the present invention to these and other communications applications. Given these various applications, transceivers other than those noted above may correspondingly be used in the appropriate applications, such as radio transceivers, optical transceivers, wireline transceivers, etc.

Referring to FIG. 5, a narrow band modulator 60 in accordance with the present invention is now described. The narrow band modulator 60 may either be used in a stand-alone fashion, as illustrated in FIG. 2, or as part of a modem, as illustrated in FIG. 1, depending upon the given application. The narrow band modulator 60 illustratively includes an input device 61 for receiving digital data to be modulated, a level mapper 62 for mapping the digital data to at least one of a plurality of different levels, and a carrier generator 63 for generating a carrier at a predetermined frequency. The levels may be voltage or current levels, as will be appreciated by those of skill in the art, depending upon the given application.

In addition, the narrow band modulator 60 also illustratively includes a counter 64 for generating a gating control signal every predetermined number of cycles of the carrier. Further, a gating device 65 outputs the level (or levels) from the level mapper 62 for a predetermined portion of a carrier cycle responsive to the gating control signal, and outputs the carrier otherwise.

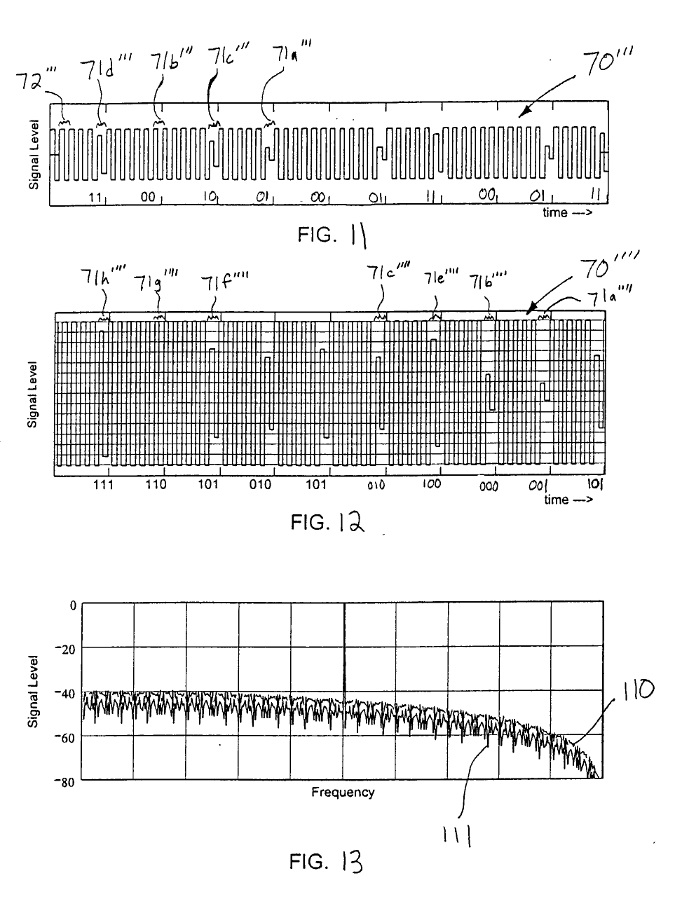

Operation of the gating device 65 will be further understood with reference to the time domain waveform diagrams of FIGS. 8-12. For clarity of illustration, each of the exemplary modulated signals 70-70″″ illustrated in FIGS. 8-12, respectively, corresponds to a same carrier and results from a gating control signal which is generated by the counter 64 every sixth carrier cycle. However, it should be noted that in an actual implementation the ratio of carrier cycles to data cycles may in fact be much higher (e.g., 30:1 or greater) depending upon the given application. Of course, other ratios of carrier cycles to data cycles may be used and are included within the scope of the present invention as well.

For the modulated signal 70, the level mapper 62 maps the digital data into a single corresponding level 71a or 71b over one half of every sixth carrier cycle 72. In this example, the total number of levels used is two, meaning that the equivalent of a single bit of data is output every sixth cycle. In other words, the level 71a corresponds to a logic 1, while the level 71b corresponds to a logic 0. For ease of reference, the appropriate digital logic value 1 or 0 is reproduced below the signal 70 at each sixth carrier cycle.

The modulated waveform 70′ (FIG. 9) is similar to the waveform 70 but differs in that a total number of four levels are used instead of two. Thus, the equivalent of two bits of digital data are output every sixth cycle, which provides twice the data bit rate of the waveform 70. Namely, the level 71a′ corresponds to a logic 01, the level 71b′ corresponds to a logic 00, the level 71c′ corresponds to a logic level 10, and the logic level 71d′ corresponds to a logic level 11. Of course, it will be appreciated by those of skill in the art that level/logic value mappings provided herein are merely exemplary, and other mappings may also be used. Furthermore, it will also be appreciated by those of skill in the art that additional bits and corresponding levels may also be used, as will be seen below.

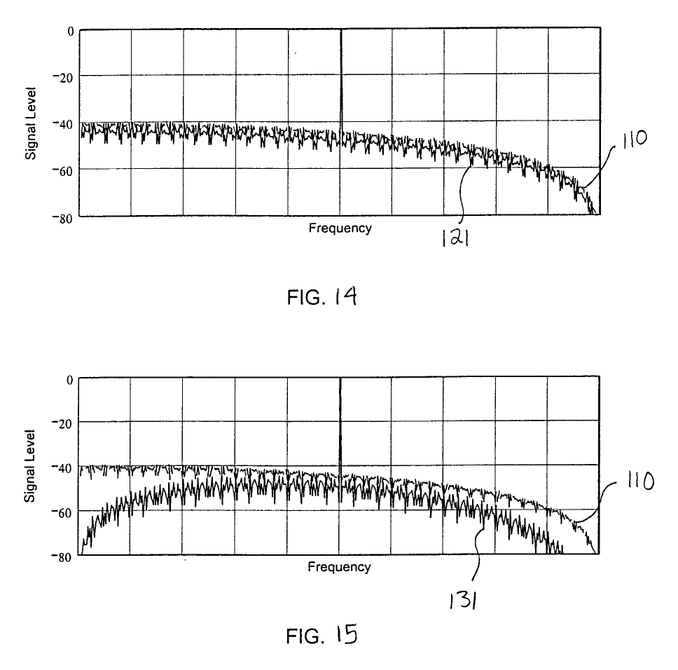

The differences between a frequency spectral response 110 for a signal modulated in accordance with the prior art missing pulse modulation technique described with reference to FIG. 7, and a frequency spectral response 111 of a signal modulated using the half-cycle, two-level narrow band modulation described with reference to FIG. 8, both with a carrier cycle to data cycle ratio of 60:1, are shown in FIG. 13. In particular, while both techniques provide a very narrow pass band at the carrier frequency, the frequency spectral response 111 exhibits reduced modulation harmonics, or minor peaks, with respect to the frequency spectral response 110 along substantially the entire illustrated frequency range. A similar reduction in modulation harmonics is also evident upon comparison of the prior art frequency spectral response 110 and a frequency spectral response 121 (FIG. 14) which corresponds to a signal modulated as described with reference to FIG. 9 and also has a 60:1 carrier cycle to data cycle ratio.

In accordance with yet another aspect of the invention, the portion of the carrier cycle over which the gating device 65 outputs the level from the level mapper 62 may advantageously be one full carrier cycle. More particularly, in the exemplary modulated signals 70″-70″″ illustrated in FIGS. 10-12, the level mapper 62 may map the digital data into a first corresponding level during a first half-cycle of each sixth carrier cycles, and to a second corresponding level during a second half-cycle of the full carrier cycle (illustratively shown with the dashed arrow in FIG. 5). In the illustrated example, an upper level is used during the first half of each sixth carrier cycle and a lower level is used during the second half, but this order may be reversed in some embodiments or other level combinations may be used, as will be appreciated by those of skill in the art.

With respect to the modulated signal 70″, a pair of first and second levels 71a″ corresponds to a logic level 1, and a second pair of first and second logic levels 71b″ corresponds to a logic level 0. For the modulated signals 70′″ and 70″″, four and eight pairs of first and second logic levels are respectively used so that the equivalent of either two or three bits of data are output every sixth carrier cycle 72′″, 72″″, which thus provide two and four times the data bit rate of the modulated signal 70″.

From the foregoing discussion and the digital data legends provided in FIGS. 8-10, it will be apparent to those skilled in the art which reference levels correspond to which data levels, so they will not be specifically listed herein to avoid undue repetition. It should be noted that various numbers of levels other than those described with reference to the exemplary embodiments above may also be used. Moreover, the level or levels may be output over other portions of a carrier cycle besides those described above.

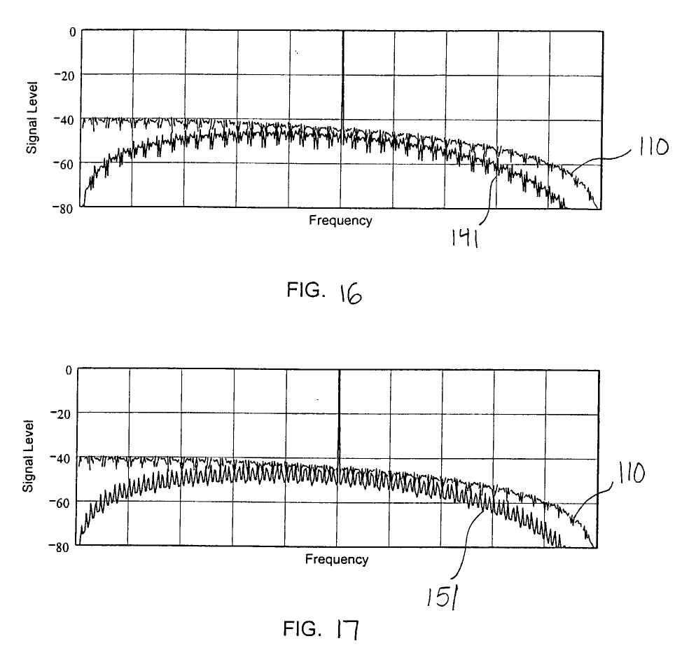

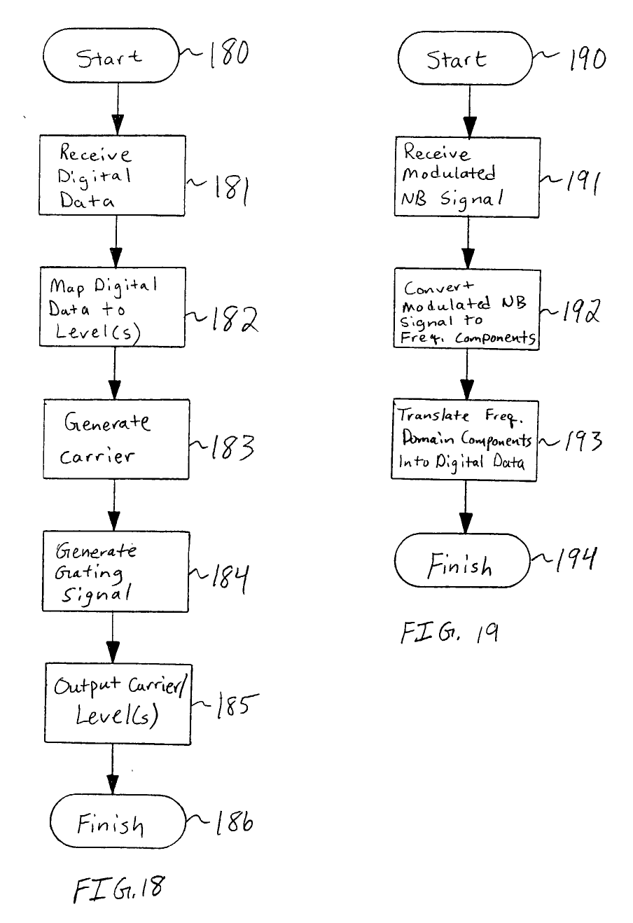

Frequency spectral responses 131, 141, and 151 for signals modulated as described with reference to FIGS. 10-12 and having a 60:1 carrier cycle to data cycle ratio are respectively illustrated in FIGS. 15-17, along with the prior art frequency spectral response 110, to demonstrate the even greater differences therebetween. That is, not only are the modulation harmonics for the full-cycle modulated waveforms of the present invention lower across substantially the entire illustrated frequency range with respect to those of the prior art missing pulse modulated signal, but the signal levels of the frequency spectral responses 131, 141, and 151 fall off dramatically near the ends of the illustrated frequency range.

Referring once again to FIG. 5, the narrow band modulator 60 may also further include a clock pulse generator 66 for generating a data clock based upon the digital data for the level mapper 62 and the gating device 65. More particularly, the digital data may in some embodiments be synchronized with the carrier frequency. The data clock indicates the frequency at which the input data is being received and is used to synchronize the mapping of digital data and the outputting thereof by the gate device 65, as will be appreciated by those of skill the art. The data clock may also be transmitted as part of the modulated signal to allow for the synchronization of the digital data following demodulation, as will be appreciated by those of skill in the art.

The narrow band modulator 60 also illustratively includes a digital-to-analog (D/A) converter 67 connected to the gating device 65, and an output interface device 68 connected to the D/A converter. In some embodiments, the level mapper 62, the counter, the gating device 65, and/or other components may be implemented in a digital signal processor (DSP), for example. Of course, implementation using discrete circuit components or other implementations may also be used, as will be appreciated by those of skill in the art. It will also be appreciated that the modulator 60 may be relatively easily implemented using conventional devices.

The carrier generator 63 may be a crystal oscillator, for example. An exemplary range for the predetermined frequency of the carrier is about 10 MHz to 2 GHz, but other frequencies may also be used depending upon the given application. Regarding the selection of the number of cycles to count for generating the gating control signal, any number may be used but a preferred range for most applications would be greater than about 30 and, more preferably, greater than about 50 to maintain modulation harmonics at least 40 dB below the carrier peak. As will be appreciated by those of skill in the art, the smaller this number becomes the greater the data throughput will be, but this will at the same time increase the modulation harmonics to some degree. As such, the number that is selected should balance the need for data throughput with the resulting modulation harmonics, which will vary depending upon the application, carrier frequencies used, etc.

Turning now to FIG. 6, a narrow band demodulator 80 in accordance with the present invention is now described. As with the modulator 60, the demodulator 80 may either be used in a stand-alone fashion, as illustrated in FIG. 2, or as part of a modem, as illustrated in FIG. 1, depending upon the given application. The narrow band demodulator 80 illustratively includes an input device 81 for receiving a modulated narrow band signal, such as the signals 70-70″″ described above. Of course, other narrow band modulated signals may also be demodulated, such as the signal 50 obtained by the prior art missing pulse method described above. Yet, when used with signals modulated in accordance with the present invention, the demodulator 80 can advantageously detect a loss of signal data, which may be problematic using techniques such as the prior art missing pulse technique, where continuous, non-changing data can result in a non-unique, pure carrier.

The narrow band demodulator 80 further illustratively includes an analog-to-digital (A/D) converter 82 connected to the input 81, and a frequency domain converter 83 connected to the A/D converter for converting the modulated narrow band signal into frequency domain components. It is noteworthy that most prior art narrow band demodulation techniques utilize time domain processing. Prior art narrow band demodulation using time domain techniques requires an exceptional transient response of the modulation source, the transmission medium and the demodulator. This is due to the edges of the time domain that need to be met and the levels that need to be held sufficient to reliably recover data with linear comparators or logic gates.

The most significant reason for using a narrow band modulation/demodulation approach is to provide a well-defined and narrow center frequency signal level while keeping the modulation harmonics or minor peaks as low as possible. Thus, the use of traditional time domain demodulation approaches can prove problematic when using narrow band modulation.

Yet, in accordance with the present invention, the nature of the carrier frequency component of the signal provided by the above described narrow band modulation is such that it allows for ready demodulation using frequency domain processing. To this end, the frequency domain converter 83 may use conventional signal processing algorithms or devices that implement Fourier transforms, wavelet transforms, etc. Moreover, since the modulated narrow band signals produced in accordance with the present invention are carrier-predominant signals, data scrambling need not be used as is required in many prior art designs to control spectral characteristics, as will be appreciated by those skilled in the art.

The narrow band demodulator 80 further illustratively includes a data translator 84 for translating the frequency domain components into the digital data based upon the level of the carrier frequency components. In particular, the data translator 84 may include an adaptive filter, for example, for training and detecting data from the carrier frequency components, although other suitable translators known to those skilled in the art may also be used.

In addition, an output buffer 85 may be connected to the data translator 84 along with a clock generator 86 for generating the data clock described above based upon the digital data. The clock generator 86 advantageously cooperates with a data driver interface 87 to output the digital data from the demodulator 80 at the same frequency at which is was input to the modulator 60, as will be appreciated by those skilled in the art. As with the modulator 60, components such as the frequency domain converter 83, data translator 84, etc., may advantageously be implemented in a DSP, though discrete circuit implementation may also be used. In fact, when included in a same narrow band modem, the above-noted components from the modulator 60 and demodulator 80 may be implemented in the same DSP, for example.

Turning to FIG. 18, a narrow band signal modulation method in accordance with the present invention is now described. The method begins (Block 180) with receiving digital data to be modulated, at Block 181, and mapping the digital data to at least one of a plurality of different levels, at Block 182, as previously described above. The method further illustratively includes generating a carrier at a predetermined frequency, at Block 183, and generating a gating control signal every predetermined number of cycles of the carrier (Block 184). Furthermore, the method also illustratively includes outputting the at least one level for a predetermined portion of a carrier cycle responsive to the gating control signal and outputting the carrier otherwise, at Block 185, as previously described above, which concludes the method (Block 186).

A narrow band signal demodulation method in accordance with the present invention is illustrated in FIG. 19. The method begins (Block 190) with receiving a modulated narrow band signal based upon a carrier frequency signal and a level periodically inserted over a predetermined portion of a carrier cycle and representing digital data, at Block 191. As discussed above, the modulated narrow band signal is then converted into frequency domain components, at Block 192, and the frequency domain components are translated into the digital data based upon levels at the carrier frequency component, at Block 193, which concludes the method (Block 194). Further method aspects of the invention will be readily apparent to those of skill in the art based upon the forgoing description and will therefore not be discussed further herein to avoid undue repetition.

Additional features of the invention may be found in co-pending patent applications entitled COMMUNICATIONS SYSTEM INCLUDING A NARROW BAND MODULATOR, attorney docket no. 55601; COMMUNICATIONS METHODS INCLUDING NARROW BAND MODULATION, attorney docket no. 55602; and COMMUNICATIONS SYSTEM INCLUDING A NARROW BAND DEMODULATOR, attorney docket no. 55603, all filed concurrently herewith. The entire disclosures of these applications are hereby incorporated herein by reference.

Many modifications and other embodiments of the invention will come to the mind of one skilled in the art having the benefit of the teachings presented in the foregoing descriptions and the associated drawings. Therefore, it is understood that the invention is not to be limited to the specific embodiments disclosed, and that modifications and embodiments are intended to be included within the scope of the appended claims.

That which is claimed is:

1. A narrow band signal demodulation method comprising:
receiving a modulated narrow band signal based upon a carrier frequency signal and a level periodically inserted over a predetermined portion of a carrier cycle and representing digital data;
converting the modulated narrow band signal into frequency domain components; and
translating the frequency domain components into the digital data based upon levels at the carrier frequency component.

2. The method of claim 1 wherein the predetermined portion of the carrier cycle is one full carrier cycle.

3. The method of claim 2 wherein the received digital data has been mapped into a first corresponding level during a first half-cycle of the full carrier cycle and into a second corresponding level during a second half-cycle of the full carrier cycle.

4. The method of claim 1 wherein the predetermined portion of the carrier cycle is one-half of the carrier cycle.

5. The method of claim 4 wherein the received digital data has been mapped into a single corresponding level over the half-cycle of the carrier cycle.

6. The method of claim 1 wherein converting comprises performing Fourier transforms.

7. The method of claim 1 wherein converting comprises performing wavelet transforms.

8. The method of claim 1 wherein the carrier frequency is in a range of about 10 MHz to 2 GHz.

9. The method of claim 1 wherein translating comprises performing adaptive filtering.

10. The method of claim 1 further comprising:
generating a data clock based upon the digital data; and
outputting the digital data based upon the data clock.

11. A narrow band signal demodulation method comprising:
receiving a modulated narrow band signal based upon a carrier frequency signal and a level periodically inserted over a full carrier cycle and representing digital data;
converting the modulated narrow band signal into frequency domain components;
translating the frequency domain components into the digital data based upon levels at the carrier frequency component;
generating a data clock based upon the digital data; and
outputting the digital data based upon the data clock.

12. The method of claim 11 wherein the received digital data has been mapped into a first corresponding level during a first half-cycle of the full carrier cycle and into a second corresponding level during a second half-cycle of the full carrier cycle.

13. The method of claim 11 wherein converting comprises performing Fourier transforms.

14. The method of claim 11 wherein converting comprises performing wavelet transforms.

15. The method of claim 11 wherein the carrier frequency is in a range of about 10 MHz to 2 GHz.

16. The method of claim 11 wherein translating comprises performing adaptive filtering.

17. A method for increasing capacity of a communications terminal comprising a receiver for receiving modulated signals from a remote terminal and at least one wide band demodulator connected to the receiver, the method comprising:
connecting at least one narrow band demodulator to the receiver for demodulating digital data from the remote terminal, the at least one narrow band demodulator comprising
an input for receiving a modulated narrow band signal based upon a carrier frequency signal and a level periodically inserted over a predetermined portion of a carrier cycle and representing digital data,
a frequency domain converter for converting the modulated narrow band signal into frequency domain components,
a data translator for translating the frequency domain components into the digital data based upon levels at the carrier frequency component;
the at least one wide band demodulator having a relatively wider frequency spectrum than a narrow frequency spectrum of the at least one narrow band modulator.

18. The method of claim 17 wherein the receiver is for receiving a plurality of modulated narrow band signals, and wherein connecting comprises connecting a plurality of narrow band demodulators to the receiver and operating at the different carrier frequencies.

19. The method of claim 17 wherein the relatively wider frequency spectrum has at least one transition frequency band associated therewith; and wherein the frequency spectrum of the at least one narrow band demodulator is in the at least one transition frequency band.

20. The method of claim 17 wherein the at least one wide band demodulator comprises at least one of a frequency shift keying (FSK), phase shift keying (PSK), quadrature amplitude modulation (QAM) demodulator, quadrature phase shift keying (QPSK), and Gaussian minimum shift keying (GMSK).

21. The method of claim 17 wherein the receiver comprises a radio receiver.

22. The method of claim 17 wherein the receiver comprises a wireline receiver.

23. The method of claim 17 wherein the receiver comprises an optical receiver.

24. The method of claim 17 wherein the predetermined portion of the carrier cycle is one full carrier cycle.

25. The method of claim 24 wherein the received digital data has been mapped into a first corresponding level during a first half-cycle of the full carrier cycle and into a second corresponding level during a second half-cycle of the full carrier cycle.

26. The method of claim 17 wherein the predetermined portion of the carrier cycle is one-half of the carrier cycle.

27. The method of claim 26 wherein the received digital data has been mapped into a single corresponding level over the half-cycle of the carrier cycle.

28. The method of claim 17 wherein the frequency domain converter performs Fourier transforms.

29. The method of claim 17 wherein the frequency domain converter performs wavelet transforms.

30. The method of claim 17 wherein the carrier frequency is in a range of about 10 MHz to 2 GHz.

31. The method of claim 17 wherein the data translator comprises an adaptive filter.

32. The method of claim 17 wherein the at least one narrow band demodulator further comprises an analog-to-digital converter connected between the input device and the frequency domain converter.

33. The method of claim 17 wherein the at least one narrow band demodulator further comprises an output buffer connected to the data translator.

34. The method of claim 17 wherein the at least one narrow band demodulator further comprises a clock generator for generating a data clock based upon the digital data.

35. The method of claim 34 wherein at least one of the frequency domain converter, the data translator, and the clock generator are implemented in a digital signal processor.
